(19) United States
(12) Patent Application Publication
(10) Pub. No.: US 2026/0013308 A1
(43) Pub. Date: Jan. 8, 2026

(54) DISPLAY DEVICE, METHOD OF MANUFACTURING THE SAME, AND ELECTRONIC DEVICE INCLUDING THE SAME

(71) Applicant: Samsung Display Co., LTD., Yongin-si (KR)

(72) Inventors: HYEOKTAE KWON, Yongin-si (KR); DOYOUB KIM, Yongin-si (KR)

(21) Appl. No.: 19/225,953

(22) Filed: Jun. 2, 2025

(30) Foreign Application Priority Data
Jul. 8, 2024 (KR) 10-2024-0089928

(51) Int. Cl. H10H 29/85; H01L 25/16

(52) U.S. Cl. CPC H10H 29/857; H01L 25/167

(57) ABSTRACT

A display device is disclosed. The display device may include a substrate including a display area in which a plurality of pixels are provided and a pad area at one side of the display area, a circuit board electrically connected to each of the plurality of pixels, spaced and/or apart (e.g., spaced apart or separated) from the substrate in a first direction, and including a first ground portion and a second ground portion each in both sides (e.g., two opposing sides), and a cover member extending from an upper portion of the circuit board to a lower portion of the circuit board, and including a first contact portion which is bent toward the first ground portion and connected to the first ground portion and a second contact portion which is bent toward the second ground portion and connected to the second ground portion.

### CROSS-REFERENCE TO RELATED APPLICATION

The present application claims priority to and the benefit of Korean Patent Application No. 10-2024-0089928, filed on Jul. 8, 2024, in the Korean Intellectual Property Office, the entire disclosure of which is incorporated herein by reference.

### BACKGROUND

### 1. Field

One or more embodiments of the present disclosure relate to a display device and a method of manufacturing the displace device. For example, one or more embodiments of the present disclosure relate to the display device to prevent a lifting phenomenon (or to reduce a degree or occurrence of a lifting phenomenon) of a cover member and the method of manufacturing the display device.

### 2. Description of the Related Art

A display device may include a display area in which a plurality of pixels are provided and a pad area in which driving chips are provided. The driving chips may provide driving signals to the plurality of pixels, and accordingly, each of the plurality of pixels may emit light. The driving chips may be electrically connected to a circuit board on the pad area. The circuit board may be electrically connected to the driving chips.

In order to prevent or reduce electrostatic discharge (ESD) phenomenon, a cover member may be attached to the driving chips and the circuit board. Because the display device have a structure in which a portion of a conductive (e.g., electrically conductive) layer included inside the circuit board is exposed to the outside for grounding, a problem, such as a lifting phenomenon, occurs because the cover member does not contact the circuit board. One or more studies have been conducted to prevent or reduce the lifting phenomenon of the cover member, such as attaching a conductive (e.g., electrically conductive) tape.

### SUMMARY

One or more aspects of embodiments of the present disclosure are directed toward a display device having an improved or enhanced durability.

One or more aspects of embodiments of the present disclosure are directed toward a method of manufacturing the display device.

Additional aspects of embodiments will be set forth in part in the description which follows and, in part, will be apparent from the description or may be learned by practice of the presented embodiments of the disclosure.

A display device according to one or more embodiments includes a substrate including a display area in which a plurality of pixels are provided and a pad area at one side of the display area, a circuit board electrically connected to each of the plurality of pixels, spaced and/or apart (e.g., spaced apart or separated) from the substrate in a first direction, and including a first ground portion and a second ground portion each provided in both sides (e.g., two opposing sides), and a cover member extending from an upper portion of the circuit board to a lower portion of the circuit board and including a first contact portion which is bent toward the first ground portion and connected to the first ground portion and a second contact portion which is bent toward the second ground portion and connected to the second ground portion.

In one or more embodiments, the circuit board may include a lower cover layer of which openings are defined in both sides (e.g., two opposing sides), an upper cover layer on the lower cover layer, and a conductive (e.g., electrically conductive) pattern between the lower cover layer and the upper cover layer, in a cross-sectional view.

In one or more embodiments, each of the first ground portion and the second ground portion may be defined by a rear surface of the conductive (e.g., electrically conductive) pattern exposed by the openings.

In one or more embodiments, the cover member may include a first area adjacent to the substrate, a second area bent along a first bending axis extending in a second direction which intersects with the first direction, and a third area spaced and/or apart (e.g., spaced apart or separated) from the first area, wherein the second area is between the first area and the third area.

In one or more embodiments, the cover member may include an insulating (e.g., electrically insulating) layer to cover an upper surface of the circuit board and a conductive (e.g., electrically conductive) layer on the insulating (e.g., electrically insulating) layer.

In one or more embodiments, each of the first contact portion and the second contact portion may be in the first area.

In one or more embodiments, the first contact portion may be defined as a first portion of the conductive (e.g., electrically conductive) layer bent toward the first ground portion along a second bending axis extending in the first direction.

In one or more embodiments, the second ground portion may be defined as a second portion of the conductive (e.g., electrically conductive) layer bent toward the second ground portion along a third bending axis parallel (e.g., substantially parallel) to the second bending axis.

In one or more embodiments, the first contact portion may protrude from one side of the cover member in the second direction, in a plan view.

In one or more embodiments, the second contact portion may protrude from another side of the cover member opposite to the one side of the cover member in a direction opposite to the second direction.

In one or more embodiments, the first contact portion and the second contact portion may be electrically connected to the first ground portion and the second ground portion through a conductive (e.g., electrically conductive) tape, respectively.

A display device according to one or more embodiments includes a substrate including a display area in which a plurality of pixels are provided and a pad area at one side of the display area, a circuit board electrically connected to each of the plurality of pixels, spaced and/or apart (e.g., spaced apart or separated) from the substrate in a first direction, and including a first ground portion and a second ground portion each in both sides (e.g., two opposing sides), and a cover member extending from an upper portion of the circuit board to a lower portion of the circuit board, and including an insulating (e.g., electrically insulating) layer to cover an upper surface of the circuit board, and of which a first recess and a second recess are defined in both sides (e.g., two opposing sides) and a conductive (e.g., electrically conductive) layer provided on the insulating (e.g., electrically insulating) layer, connected to the first ground portion through the first recess, and connected to the second ground portion through the second recess.

In one or more embodiments, the cover member may include a first area adjacent to the substrate, a second area bent along a first bending axis extending in a second direction which intersects with the first direction, and a third area spaced and/or apart (e.g., spaced apart or separated) from the first area, wherein the second area is between the first area and the third area.

In one or more embodiments, each of the first recess and the second recess may be in the third area.

In one or more embodiments, the first recess may be recessed from one side of the insulating (e.g., electrically insulating) layer in a direction opposite to the second direction and may expose the first ground portion, and the second recess may be recessed from another side opposite to the one side of the insulating (e.g., electrically insulating) layer in the second direction and may expose the second ground portion.

In one or more embodiments, a first portion of the conductive (e.g., electrically conductive) layer, which is connected to the first ground portion through the first recess, may be electrically connected to the first ground portion through a first conductive (e.g., electrically conductive) tape, and a second portion of the conductive (e.g., electrically conductive) layer, which is connected to the second ground portion through the second recess, may be electrically connected to the second ground portion through a second conductive (e.g., electrically conductive) tape.

A method of manufacturing a display device according to one or more embodiments includes electrically connecting a display panel including a plurality of pixels to emit light to a circuit board, providing a first ground portion and a second ground portion in both sides (e.g., two opposing sides) of a rear surface of the circuit board, providing a cover member including a first contact portion and a second contact portion on an upper surface of the circuit board, connecting the first contact portion to the first ground portion by bending the cover member along a first bending axis extending in a first direction, and connecting the second contact portion to the second ground portion by bending the cover member along the first bending axis.

In one or more embodiments, each of the first contact portion and the second contact portion may protrude from both sides (e.g., two opposing sides) of the circuit board in a plan view, in connecting of the first contact portion to the first ground portion, the first contact portion may be bent toward the first ground portion along a second bending axis extending in a second direction which intersects with the first direction, and in connecting of the second contact portion to the second ground portion, the second contact portion may be bent toward the second ground portion along a third bending axis parallel (e.g., substantially parallel) to the second bending axis.

In one or more embodiments, the cover member may include a conductive (e.g., electrically conductive) layer including the first contact portion and the second contact portion and an insulating (e.g., electrically insulating) layer under the conductive (e.g., electrically conductive) layer and in which a first recess exposing the first contact portion and a second recess exposing the second contact portion are defined.

In one or more embodiments, in connecting of the first contact portion, the cover member may be bent along the first bending axis so that the first contact portion and the first ground portion are electrically connected to each other through the first recess, and in connecting of the second contact portion to the second ground portion, the cover member may be bent along the first bending axis so that the second contact portion and the second ground portion are electrically connected to each other through the second first recess.

In a display device according to one or more embodiments of the present disclosure, a cover member may include a first contact portion bent toward a first ground portion of a circuit board and connected to the first ground portion and a second contact portion bent toward a second ground portion of the circuit board and connected to the second ground portion. In one or more embodiments, the contact between the cover member and the circuit board may be improved or enhanced, and a contact failure between the cover member and the circuit board may be prevented (or a degree or occurrence of such contact failure may be reduced). In one or more embodiments, a durability of the display device may be improved or enhanced.

In the display device according to one or more embodiments of the present disclosure, the cover member may include an insulating (e.g., electrically insulating) layer in which a first recess and a second recess are defined and a conductive (e.g., electrically conductive) layer including the first contact portion and the second contact portion. In one or more embodiments, the first contact portion may be connected to the first ground portion through the first recess, and the second contact portion may be connected to the second ground portion through the second recess. In one or more embodiments, the contact between the cover member and the circuit board may be improved or enhanced, and the contact failure between the cover member and the circuit board may be prevented (or a degree or occurrence of such contact failure may be reduced). In one or more embodiments, the durability of the display device may be improved or enhanced.

An electronic device includes the display device as described in one or more embodiments.

The electronic device may be a smartphone, a television, a monitor, a tablet, an electric vehicle, a mobile phone, a tablet personal computer (PC), a mobile communication terminal, an electronic notebook, an electronic book, a portable multimedia player (PMP), a navigation device, an ultra-mobile PC (UMPC), a laptop computer, a billboard, an Internet of Things (IOT) device, a smartwatch, a watch phone, and/or a head-mounted display (HMD).

### BRIEF DESCRIPTION OF THE DRAWINGS

Illustrative, non-limiting embodiments of the present disclosure will be more clearly understood from the following more detailed description in conjunction with the accompanying drawings.

FIG. 1 is a perspective view illustrating a display device according to one or more embodiments of the present disclosure.

FIG. 2 is a perspective view illustrating the display device having a cover member of FIG. 1 separated.

FIG. 3 is a view illustrating a portion of the display device of FIG. 1.

FIG. 4 is a plan view illustrating a display device not having a cover member of FIG. 1.

FIG. 5 is a plan view illustrating a state before the display panel and circuit board of FIG. 4 are combined.

FIG. 6 is a cross-sectional view illustrating a cross-section taken along a line X-X′ of FIG. 4.

FIG. 7 is a bottom view illustrating the display device of FIG. 4.

FIG. 8 is a cross-sectional view illustrating a cross-section taken along a line I-I′ of FIG. 1.

FIG. 9 is a cross-sectional view illustrating a cross-section taken along a line II-II′ of FIG. 1.

FIGS. 10-15 each is a view illustrating a method of manufacturing the display device of FIG. 1 according to one or more embodiments.

FIG. 16 is a perspective view illustrating a display device according to one or more embodiments of the present disclosure.

FIG. 17 is a cross-sectional view illustrating a cross-section taken along a line III-III′ of FIG. 16.

FIGS. 18-22 each is a view illustrating a method of manufacturing the display device of FIG. 16 according to one or more embodiments.

### DETAILED DESCRIPTION

Hereinafter, display devices and methods of manufacturing the display devices in accordance with one or more embodiments of the present disclosure will be described in more detail with reference to the accompanying drawings. The subject matter of the present disclosure may, however, be embodied in one or more different forms and should not be construed as being limited to one or more embodiments set forth herein.

The same reference numerals are used for substantially the same components or elements in the drawings, and redundant descriptions of substantially the same components or elements may not be provided.

Rather, these embodiments are provided as examples so that the present disclosure will be thorough and complete and will fully convey the aspects and features of the present disclosure to those skilled in the art.

It will be understood that, although the terms, “first,” “second,” “third,” and/or the like, may be used herein to describe one or more elements, components, areas, layers, and/or sections, these elements, components, areas, layers, and/or sections should not be limited by these terms. These terms are only used to distinguish an element, a component, an area, a layer, and/or a section from another element, component, area, layer, and/or section. Thus, a first element, a first component, a first area, a first layer, and/or a first section disclosed in the present disclosure may be termed a second element, a second component, a second area, a second layer, and/or a second section without departing from the spirit and scope of the present disclosure.

The terminology used herein is for the purpose of describing certain embodiments only and is not intended to be limiting of the present disclosure. As used herein, the singular forms “a,” “an,” and “the” are intended to include the plural forms as well, unless the context clearly indicates otherwise.

It will be further understood that the terms “include,” “including,” “have,” and/or “having,” if (e.g., when) used in the present disclosure, specify the presence of stated features, integers, steps, operations, elements, components, and/or groups thereof but do not preclude the presence or addition of one or more other features, integers, steps, operations, elements, components, and/or groups thereof.

Unless otherwise defined, all terms (including technical and scientific terms) used herein have substantially the same meaning as generally understood by one of ordinary skill in the art to which the present disclosure belongs. It will be further understood that terms, such as those defined in dictionaries that are generally available or generally used, should be interpreted as having a meaning that is consistent with their meaning in the context of the relevant art and will not be interpreted in an idealized or overly formal sense unless expressly so defined herein.

All methods described herein may be performed in a suitable order unless otherwise indicated herein or otherwise clearly contradicted by context. The use of any and all examples, or exemplary language (e.g., “such as”), is intended merely to better illustrate the present disclosure and does not pose a limitation on the scope of the present disclosure unless otherwise claimed. No language in the specification should be construed as indicating any non-claimed element as essential to the practice of the present disclosure as used herein.

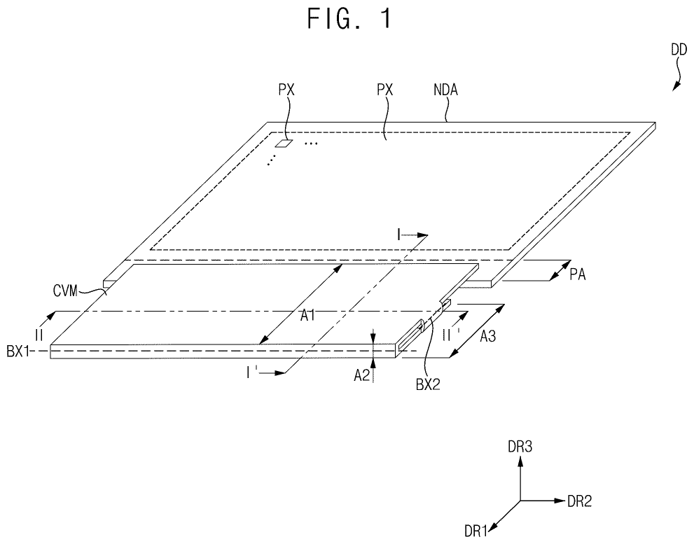

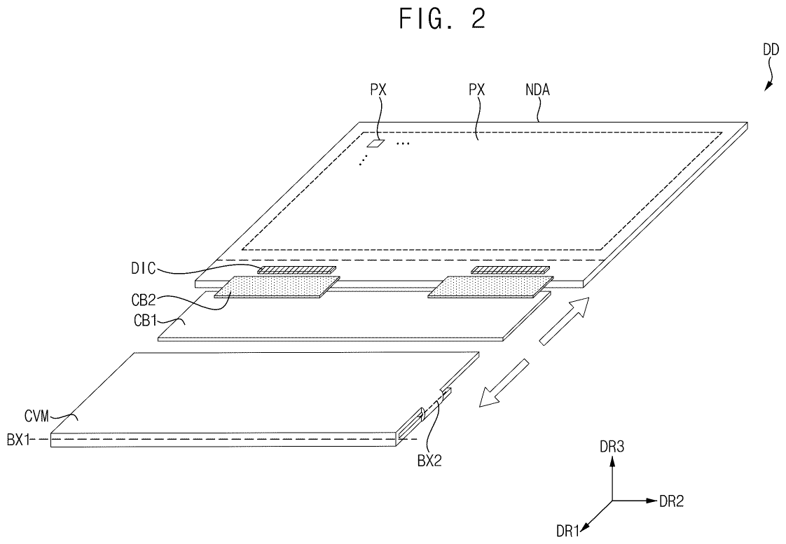

FIG. 1 is a perspective view illustrating a display device according to one or more embodiments of the present disclosure. FIG. 2 is a perspective view illustrating the display device having a cover member of FIG. 1 separated.

In one or more embodiments, a plane may be defined by a first direction DR1 and a second direction DR2 which intersects with the first direction DR1. For example, the first direction DR1 and the second direction DR2 may be perpendicular (e.g., substantially perpendicular) to each other. In one or more embodiments, a third direction DR3 may be perpendicular (e.g., substantially perpendicular) to the plane.

Referring to FIGS. 1-2, a display device DD according to one or more embodiments of the present disclosure may include a display area DA, non-display area NDA, and a pad area PA. The display device DD may include a display panel DP, a driving chip DIC, a first circuit board CB1, a second circuit board CB2, and a cover member CVM. As the display device DD includes the display panel DP, the display panel DP may also include the display area DA, the non-display area NDA, and the pad area PA.

The display area DA may be an area to generate light and/or display an image by controlling the transmittance of light provided from an external light source. At least one pixel PX that is to emit light may be in the display area DA. A plurality of pixels PX may be in the display area DA. For example, the pixels PX may be in the first direction DR1 and the second direction DR2 in the display area DA to provide a matrix. The pixels PX may include sub-pixels that are to emit light of different colors. For example, the sub-pixels may include a first sub-pixel, a second sub-pixel, and a third sub-pixel, and the first sub-pixel may be to emit a first light, the second sub-pixel may be to emit a second light, and the third sub-pixel may be to emit a third light. In one or more embodiments, the first light may be red, the second light may be green, and the third light may be blue. However, color of light emitted by each of the sub-pixels included in the pixel PX according to one or more embodiments of the present disclosure may not be limited thereto and may be to emit light having one or more colors, such as magenta, cyan, and yellow.

The non-display area NDA may surround at least a portion of the display area DA. For example, the non-display area NDA may entirely (e.g., substantially entirely) surround the display area DA in a plan view. The non-display area NDA may be defined as an area that does not emit light and does not generate an image. A driver to drive the pixel PX may be in the non-display area NDA. The driver may provide a signal and/or voltage to the pixel PX. For example, the driver may include a scan driver, a light-emitting driver, a power voltage generator, a timing controller, and/or the like.

The pad area PA may be spaced and/or apart (e.g., spaced apart or separated) from one side of the display area DA. For example, the pad area PA may be spaced and/or apart (e.g., spaced apart or separated) from the one side of the display area DA in the first direction DR1. The pad area PA may be spaced and/or apart (e.g., spaced apart or separated) from the display area DA in the first direction DR1 with the non-display area NDA therebetween. For example, the non-display area NDA may be between the pad area PA and the display area DA. The driving chip DIC that is to apply a data signal to the pixel PX may be in the pad area PA.

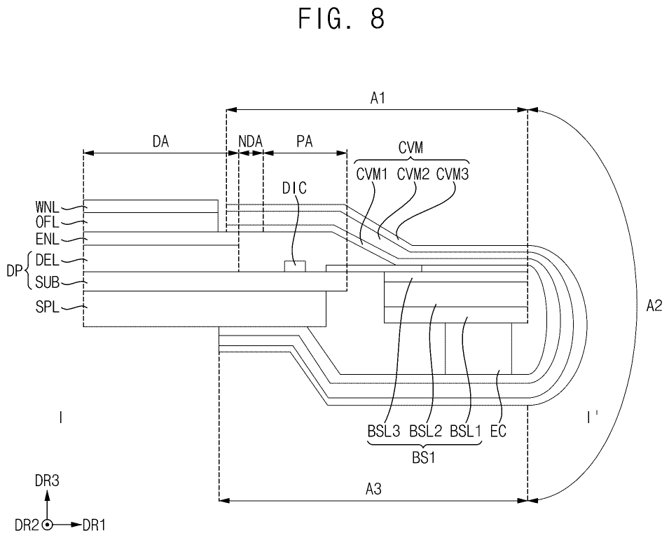

The first circuit board CB1 may be spaced and/or apart (e.g., spaced apart or separated) from the display panel DP in the first direction DR1. The first circuit board CB1 may be electrically connected to an electronic component (e.g., an electronic component EC of FIG. 8). The first circuit board CB1 may be to generate a scan control signal, a data control signal, and image data by using an image signal and a plurality of timing signals received from the electronic component. The generated scan control signal, the data control signal, and the image data may be provided to the driving chip DIC through the first circuit board CB1. In one or more embodiments, the first circuit board CB1 may be referred to as a circuit board.

The second circuit board CB2 may electrically connect the first circuit board CB1 and the driving chip DIC to each other. For example, one end of the second circuit board CB2 may contact the driving chip DIC, and another end of the second circuit board CB2 opposite to the one end may contact the first circuit board CB1. The second circuit board CB2 may overlap a portion of each of the display panel DP and the first circuit board CB1 in a plan view.

The cover member CVM may cover the first circuit board CB1 and the driving chip DIC. The cover member CVM may be attached to an upper surface of the first circuit board CB1 and may be bent along a first bending axis BX1 extending in a second direction DR2. For example, as the cover member CVM is bent along the first bending axis BX1, the cover member CVM may extend from the upper surface of the first circuit board CB1 to a rear surface of the first circuit board CB1. In one or more embodiments, the cover member CVM may also cover the rear surface of the first circuit board CB1. The cover member CVM may be a protective cover extending from a pad area PA of the display panel DP to a lower structure of the display panel DP to protect the first circuit board CB1, the second circuit board CB2, and the driving chip DIC.

The cover member CVM may include a first area A1, a second area A2, and a third area A3. The first area A1 may be adjacent to the display panel DP. For example, the first area A1 may partially overlap the pad area PA of the display panel DP in a plan view. The second area A2 may be an area where the cover member CVM is bent along the first bending axis BX1. The third area A3 may be spaced and/or apart (e.g., spaced apart or separated) from the first area A1, wherein the second area A2 is between the first area A1 and the third area A3. As the cover member CVM is bent in the second area A2, the first area A1 and the third area A3 may overlap each other in a plan view. However, the first area A1 may be an area facing the upper surface of the first circuit board CB1, and the third area A3 may be an area facing the rear surface of the first circuit board CB1.

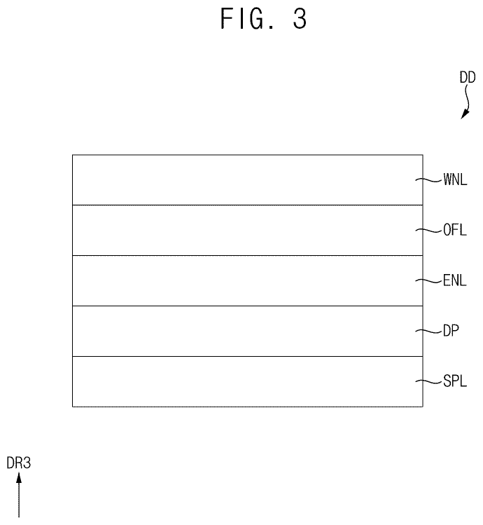

FIG. 3 is a view illustrating a portion of the display device of FIG. 1. For example, FIG. 3 is a view illustrating the display panel DP and the layers on and under the display panel DP which are included in the display device DD.

Referring to FIG. 3, the display device DD may include the display panel DP, an encapsulation layer ENL, an optical function layer OFL, a window layer WNL, and a lower plate layer SPL.

The display panel DP may include the pixel (e.g., the pixel PX of FIG. 1). For example, the pixel may include a substrate, an insulating (e.g., electrically insulating) layer on the substrate, at least one transistor on the substrate, and a light-emitting element electrically connected to the transistor. The transistor may include a low temperature polycrystalline silicon LTPS. However, a material included in the transistor according to one or more embodiments of the present disclosure may not be limited thereto. For example, the transistor may include an oxide semiconductor.

The encapsulation layer ENL may be on the display panel DP. The encapsulation layer ENL may be to protect the pixel included in the display panel DP. For example, the encapsulation layer ENL may cover the light-emitting element included in the pixel. In one or more embodiments, the encapsulation layer ENL may be a glass substrate. The encapsulation layer ENL may be combined to the display panel DP through a sealing member including a frit and/or the like. However, a structure of the encapsulation layer ENL according to one or more embodiments of the present disclosure may not be limited thereto, and the encapsulation layer ENL may have a multilayer structure. For example, the encapsulation layer ENL may have at least one inorganic layer including an inorganic insulating (e.g., electrically insulating) material and at least one organic layer including an organic insulating (e.g., electrically insulating) material.

The optical function layer OFL may be on the encapsulation layer ENL. The optical function layer OFL may be a layer that is on the display panel DP and is to perform an optical function of controlling light. In one or more embodiments, the optical function layer OFL may be a polarizing layer. For example, the optical function layer OFL may be to polarize light incident from an outside onto the display panel DP. The optical function layer OFL may be elongated in one direction. An elongation direction of the optical function layer OFL may be an absorption axis, and the direction perpendicular (e.g., substantially perpendicular) to the elongation direction may be a transmission axis. However, the optical function layer OFL according to one or more embodiments of the present disclosure may not be limited thereto, and the optical function layer OFL may not include a polarizing layer and may include a color filter. In one or more embodiments, the display device DD may have a structure that does not include a polarizing layer.

The window layer WNL may be on the optical function layer OFL. In one or more embodiments, the window layer WNL may be ultrathin glass (UTG). For example, the window layer WNL may include a soda-lime glass, an alkali aluminosilicate glass, a borosilicate glass, a lithium aluminosilicate glass, and/or the like. These types or kinds of glasses may be used alone or in combination. However, the window layer WNL of the present disclosure may not be limited thereto and may include one or more suitable materials, such as a plastic.

The lower plate layer SPL may be under the display panel DP. In one or more embodiments, the lower plate layer SPL may have a multilayer structure. For example, the lower plate layer SPL may include a support layer that is to support the lower plate layer SPL, a heat dissipation layer that is to perform a heat dissipation function, and a cushion layer that is to absorb shock. However, a structure of the lower plate layer SPL according to one or more embodiments of the present disclosure may not be limited thereto, and the lower plate layer SPL may have a single-layer structure.

However, a laminated structure of the display device DD according to one or more embodiments of the present disclosure may not be limited thereto, and one or more suitable types or kinds of layers may further be included in the display device DD, and/or the layers on the upper and/or lower portions of the display panel DP may not be provided. For example, a protective layer including a transparent (e.g., substantially transparent) polymer film may be on the window layer WNL.

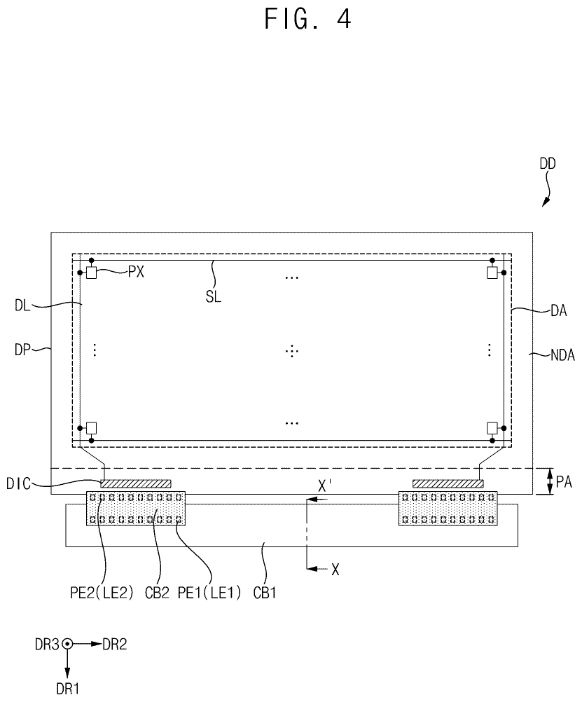

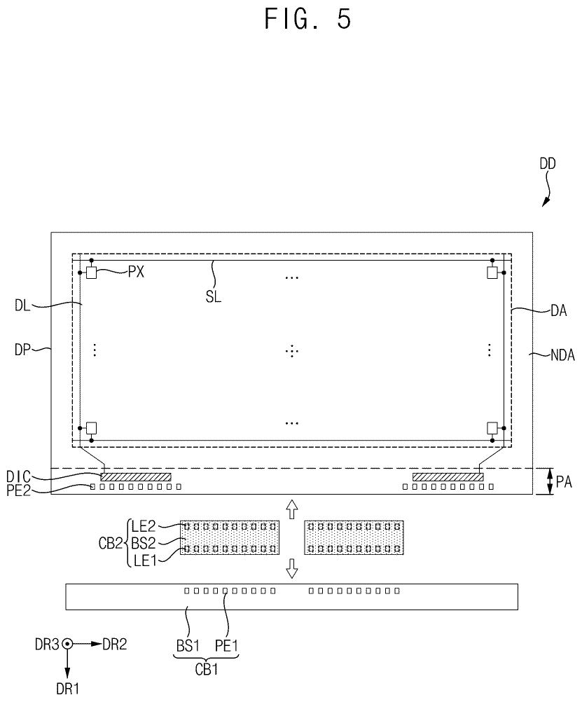

FIG. 4 is a plan view illustrating a display device not having a cover member of FIG. 1. FIG. 5 is a plan view illustrating a state before the display panel and the circuit board of FIG. 4 are combined.

Referring to FIGS. 4-5, the pixel PX may be electrically connected to a data line DL extending from the pad area PA to the display area DA. The data line DL may be electrically connected to the driving chip DIC. The pixel PX may be electrically connected to a scan line SL extending from the scan driver in the non-display area NDA to the display area DA.

The first circuit board CB1 may include a first pad electrode PE1 and a first base substrate BS1. The first circuit board CB1 may be electrically connected to the second circuit board CB2 and the driving chip DIC through the first pad electrode PE1. In one or more embodiments, the first circuit board CB1 may be to transmit a data control signal to the data line DL electrically connected to the driving chip DIC through the first pad electrode PE1. The first pad electrode PE1 may overlap the second circuit board CB2 in a plan view. In one or more embodiments, the first pad electrode PE1 may include a conductive (e.g., electrically conductive) material. For example, the conductive (e.g., electrically conductive) material may include a metal, an alloy, a metal nitride, a conductive (e.g., electrically conductive) metal oxide, a transparent (e.g., substantially transparent) conductive (e.g., electrically conductive) material, and/or the like. These conductive (e.g., electrically conductive) materials may be used alone or in combination with each other.

In one or more embodiments, the first circuit board CB1 may be a printed circuit board (PCB). The first base substrate BS1 may be rigid (e.g., substantially rigid). However, the first circuit board CB1 according to one or more embodiments of the present disclosure may not be limited thereto, and the first base substrate BS1 may be flexible (e.g., substantially flexible).

The display panel DP may include a second pad electrode PE2. The second pad electrode PE2 may be in the pad area PA. The second pad electrode PE2 may be spaced and/or apart (e.g., spaced apart or separated) from the driving chip DIC in the first direction DR1. The driving chip DIC may be electrically connected to the second pad electrode PE2. For example, the driving chip DIC may be electrically connected to the second pad electrode PE2 through wires extending from the driving chip DIC to the second pad electrode PE2. In one or more embodiments, the second pad electrode PE2 may include a conductive (e.g., electrically conductive) material. For example, the conductive (e.g., electrically conductive) material may include a metal, an alloy, a metal nitride, a conductive (e.g., electrically conductive) metal oxide, a transparent (e.g., substantially transparent) conductive (e.g., electrically conductive) material, and/or the like. These conductive (e.g., electrically conductive) materials may be used alone or in combination with each other.

The second circuit board CB2 may include a first lead electrode LE1, a second lead electrode LE2, and a second base board BS2. The first lead electrode LE1 of the second circuit board CB2 may be electrically connected to the first pad electrode PE1 of the first circuit board CB1. The first lead electrode LE1 may be to overlap the first pad electrode PE1 in a plan view. The second lead electrode LE2 may be electrically connected to the second pad electrode PE2 of the display panel DP. The second lead electrode LE2 may be to overlap the second pad electrode PE2 in a plan view. For example, the second circuit board CB2 may be to electrically connect the first circuit board CB1 and the driving chip DIC through the first lead electrode LE1 and the second lead electrode LE2. In one or more embodiments, the second circuit board CB2 may be a flexible (e.g., substantially flexible) printed circuit board (FPCB). For example, the second base board BS2 may be flexible (e.g., substantially flexible).

In one or more embodiments, the driving chip DIC may be coupled to the display panel DP. For example, the driving chip DIC may be on a substrate included in the display panel DP (e.g., the substrate SUB of FIG. 8). For example, the driving chip DIC may be mounted in the display device DD in a structure, such as a chip on glass (COG) and/or a chip on plastic (COP). However, a mounting structure of the driving chip DIC according to one or more embodiments of the present disclosure may not be limited thereto, and the driving chip DIC may be mounted in the display device DD in a structure, such as a chip on film (COF) which the driving chip DIC is on a film.

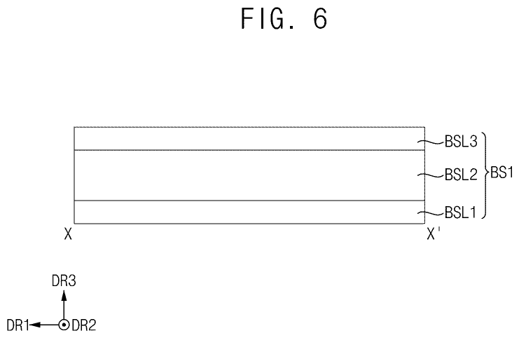

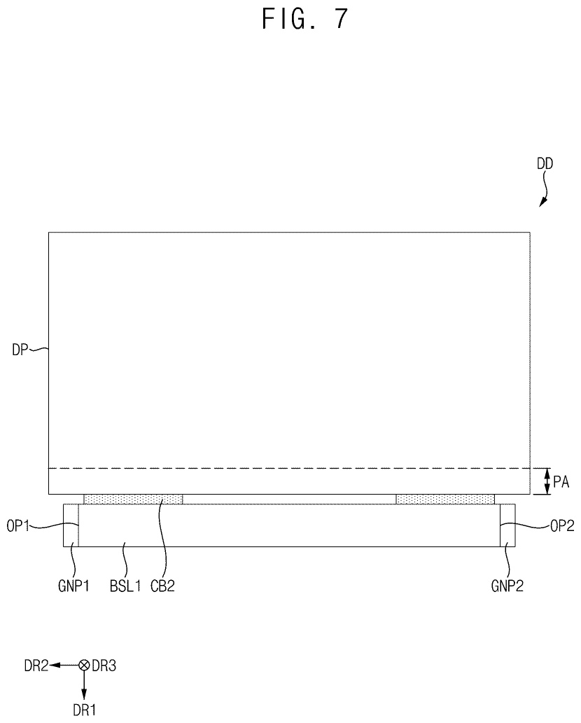

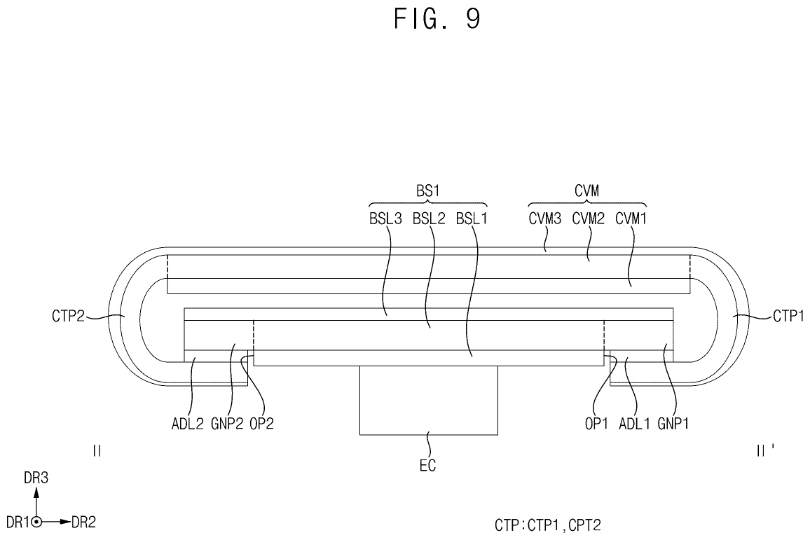

FIG. 6 is a cross-sectional view illustrating a cross-section taken along a line X-X′ of FIG. 4. FIG. 7 is a bottom view illustrating the display device of FIG. 4. FIG. 8 is a cross-sectional view illustrating a cross-section taken along a line I-I′ of FIG. 1. FIG. 9 is a cross-sectional view illustrating a cross-section taken along a line II-II′ of FIG. 1.

Referring to FIGS. 6-9, the first base substrate BS1 included in the first circuit board (e.g., the first circuit board CB1 of FIG. 4) may include a lower cover layer BSL1, a conductive pattern BSL2, and an upper cover layer BSL3. The cover member CVM may include a first insulating layer CVM1, a conductive layer CVM2, and a second insulating layer CVM3. The display panel DP may include the substrate SUB and a display element layer DEL. The display device DD may include a first adhesive layer ADL1, a second adhesive layer ADL2, and an electronic component EC. In one or more embodiments, the first insulating layer CVM1 may be referred to as an insulating (e.g., electrically insulating) layer. In one or more embodiments, the first adhesive layer ADL1 and the second adhesive layer ADL2 may be referred to as a conductive (e.g., electrically conductive) tape.

The conductive pattern BSL2 may be on the lower cover layer BSL1. The upper cover layer BLS3 may be on the conductive pattern BSL2. For example, the conductive pattern BSL2 may be between the lower cover layer BSL1 and the upper cover layer BLS3.

Each of the lower cover layer BSL1 and the upper cover layer BLS3 may include an insulating (e.g., electrically insulating) material. For example, the insulating (e.g., electrically insulating) material may include a solder resist. Each of the lower cover layer BSL1 and the upper cover layer BLS3 may cover the conductive pattern BSL2 and may be to prevent a short phenomenon (or to reduce a degree or occurrence of a short phenomenon) that is generated if (e.g., when) the conductive pattern BSL2 is exposed to an air. The conductive pattern BSL2 may include a conductive (e.g., electrically conductive) material. For example, the conductive (e.g., electrically conductive) material may include copper (Cu). However, materials included in each of the lower cover layer BSL1, the conductive pattern BSL2, and the upper cover layer BLS3 according to one or more embodiments of the present disclosure may not be limited thereto. In one or more embodiments, a structure of the first circuit board according to one or more embodiments of the present disclosure may not be limited thereto, and the first circuit board may include four or more layers or two or fewer layers. For example, the first circuit board may further include at least one prepreg layer and/or at least one circuit layer including a conductive (e.g., electrically conductive) material to improve or enhance rigidity.

The conductive pattern BSL2 may include a first ground portion GNP1 and a second ground portion GNP2 each on both sides (e.g., two opposing sides) of the conductive pattern BSL2. The first ground portion GNP1 and the second ground portion GNP2 may be portions of the first circuit board for grounding. An opening may be defined on both sides (e.g., two opposing sides) of the lower cover layer BSL1 to expose a rear surface of the conductive pattern BSL2 (e.g., a surface facing in a opposite direction to the third direction DR3). The opening according to one or more embodiments may include a first opening OP1 in a side facing the second direction DR2 of the lower cover layer BSL1 and a second opening OP2 in a side facing the opposite direction of the second direction DR2 of the lower cover layer BSL1. The first opening OP1 may expose the first ground portion GNP1. In one or more embodiments, the second opening OP2 may expose the second ground portion GNP2. For example, each of the first ground portion GNP1 and the second ground portion GNP2 may be an open ground. Although the first circuit board according to one or more embodiments of the present disclosure is described as including an open ground on the rear surface, the first circuit board may not be limited thereto, and the first circuit board may further include an open ground on the upper surface.

In one or more embodiments, the first ground portion GNP1 and the lower cover layer BSL1 may together define a step. In one or more embodiments, the second grounding portion GNP2 and the lower cover layer BSL1 may define a step together. For example, steps may be defined on both sides (e.g., two opposing sides) of the first base substrate BS1 as the first grounding portion GNP1 and the second grounding portion GNP2 are exposed through the first opening OP1 and the second opening OP2.

The conductive layer CVM2 may be on the first insulating layer CVM1. The second insulating layer CVM3 may be on the conductive layer CVM2. The first insulating layer CVM1 may cover an upper surface of the first circuit board. For example, the first insulating layer CVM1 may cover a portion of the upper cover layer BSL3. Each of the first insulating layer CVM1 and the second insulating layer CVM3 may include an insulating (e.g., electrically insulating) material. The conductive layer CVM2 may include a conductive (e.g., electrically conductive) material. For example, the conductive layer CVM2 may include aluminum (AI). However, the conductive (e.g., electrically conductive) material included in the conductive layer CVM2 according to one or more embodiments of the present disclosure may not be limited thereto.

The conductive layer CVM2 may include a first contact portion CTP1 and a second contact portion CTP2. The conductive layer CVM2 may be electrically connected to the conductive pattern BSL2. For example, the first ground portion GNP1 may be electrically connected to the first contact portion CTP1, and the second ground portion GNP2 may be electrically connected to the second contact portion CTP2. The first adhesive layer ADL1 may be between the first contact portion CTP1 and the first ground portion GNP1. In one or more embodiments, the second adhesive layer ADL2 may be between the second contact portion CTP2 and the second ground portion GNP2. In one or more embodiments, the first ground portion GNP1 may be electrically connected to the first contact portion CTP1 through the first adhesive layer ADL1, and the second ground portion GNP2 may be electrically connected to the second contact portion CTP2 through the second adhesive layer ADL2. In one or more embodiments, the first adhesive layer ADL1 and the second adhesive layer ADL2 may be conductive (e.g., electrically conductive) tapes.

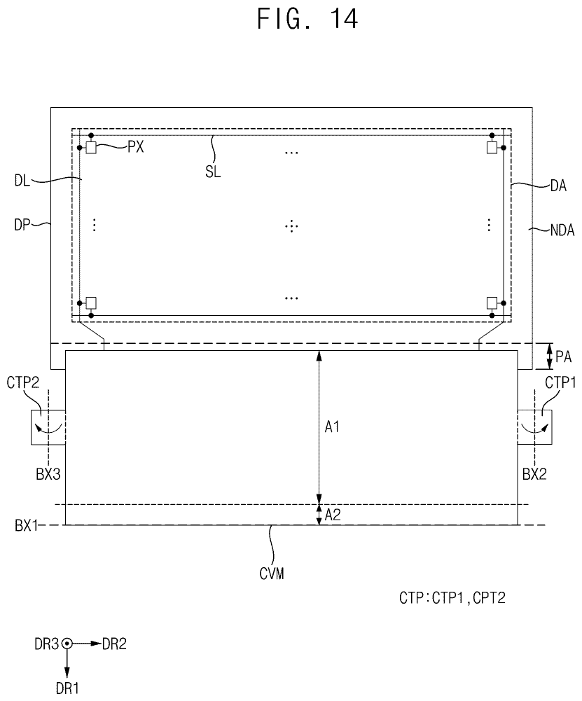

The first contact portion CTP1 may be bent toward the first ground portion GNP1 along a second bending axis (e.g., the second bending axis BX2 of FIG. 14) parallel (e.g., substantially parallel) to the first direction DR1. For example, the first contact portion CTP1 may be a part of the conductive layer CVM2 that is bent toward the first ground portion GNP1 along the second bending axis. The second contact portion CTP2 may be bent toward the second ground portion GNP2 along a third bending axis (e.g., the third bending axis BX3 of FIG. 14) parallel (e.g., substantially parallel) to the first direction DR1. For example, the second contact portion CTP2 may be a second portion of the conductive layer CVM2 that is bent toward the second ground portion GNP2 along the third bending axis. In one or more embodiments, the cover member CVM may have a shape bent along each of the first bending axis (e.g., the bending axis BX1 of FIG. 1), the second bending axis, and the third bending axis.

In one or more embodiments, the first contact portion CTP1 and the second contact portion CTP2 may be in the first area A1. For example, the first contact portion CTP1 and the second contact portion CTP2 may be bent toward the lower portion of the first base substrate BS1 within the first area A1 corresponding to the upper surface of the cover member CVM. In one or more embodiments, the second insulating layer CVM3 may cover the upper surfaces of the first contact portion CTP1 and the second contact portion CTP2. In one or more embodiments, the lower cover layer CVM1 may not cover the rear surface of the first contact portion CTP1 and the second contact portion CTP2.

The substrate SUB may be provided as a base of the display panel DP. The driving chip DIC and the second circuit board CB2 may be on the substrate SUB. In one or more embodiments, the substrate SUB may include a glass, a quartz, a plastic, and/or the like. The display element layer DEL may be on the substrate SUB. The display element layer DEL may include the transistor, the light-emitting element, and/or the like. In one or more embodiments, in a cross-sectional view, one end of the substrate SUB facing the first direction DR1 may protrude in the first direction DR1 from one end of the display element layer DEL facing the first direction DR1. The driving chip DIC may be spaced and/or apart (e.g., spaced apart or separated) from the display element layer DEL in the first direction DR1.

The encapsulation layer ENL may be on the display element layer DEL. In a cross-sectional view, the one end of the display element layer DEL facing the first direction DR1 may protrude in the first direction DR1 from one end of the encapsulation layer ENL facing the direction DR1. In one or more embodiments, an upper portion of the display element layer DEL and a portion of the cover member CVM may contact. In one or more embodiments, the cover member CVM may extend from a portion in contact with the display element layer DEL to a portion contacting the lower plate layer SPL. The lower cover layer CVM1 may partially contact each of the display element layer DEL and the lower plate layer SPL.

The electronic component EC may be between the lower cover layer BSL1 of the first circuit board and the first insulating layer CVM1 of the cover member CVM. The electronic component EC may be electrically connected to the first circuit board and may be to transmit the image signal and the plurality of timing signals to the first circuit board. As described in one or more embodiments, in the display device DD, the cover member CVM may include the first contact member CTP1 that is bent toward the first ground member GNP1 of the first circuit board and connected to the first ground member GNP1, and a second contact member CTP2 that is bent toward the second ground member GNP2 of the first circuit board and connected to the second ground member GNP2. In one or more embodiments, a contact between the cover member CVM and the first circuit board may be improved or enhanced, and a contact failure between the cover member CVM and the first circuit board may be prevented (or a degree or occurrence of such contact failure may be reduced). In one or more embodiments, the durability of the display device DD may be improved or enhanced.

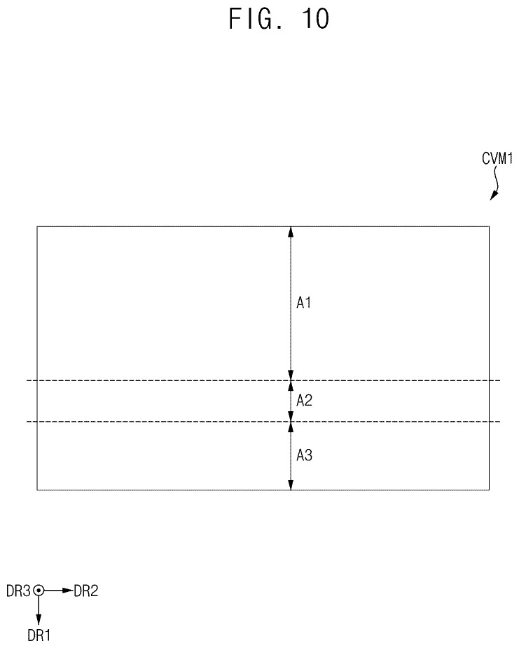

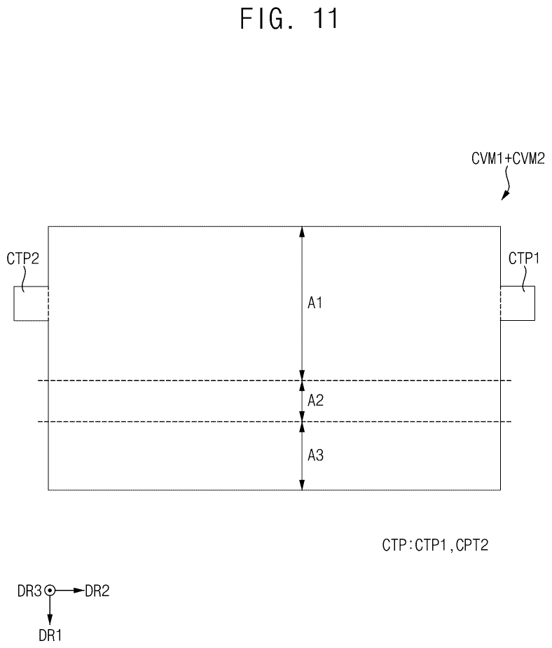

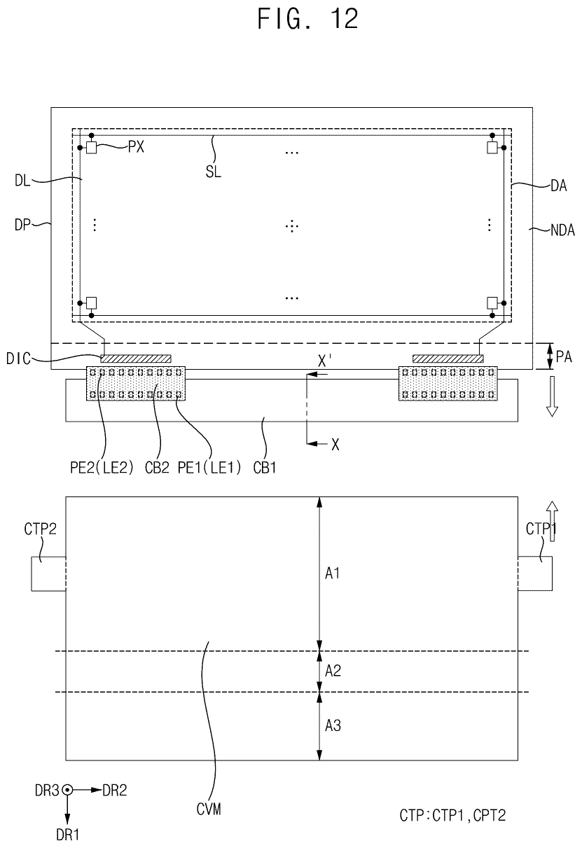

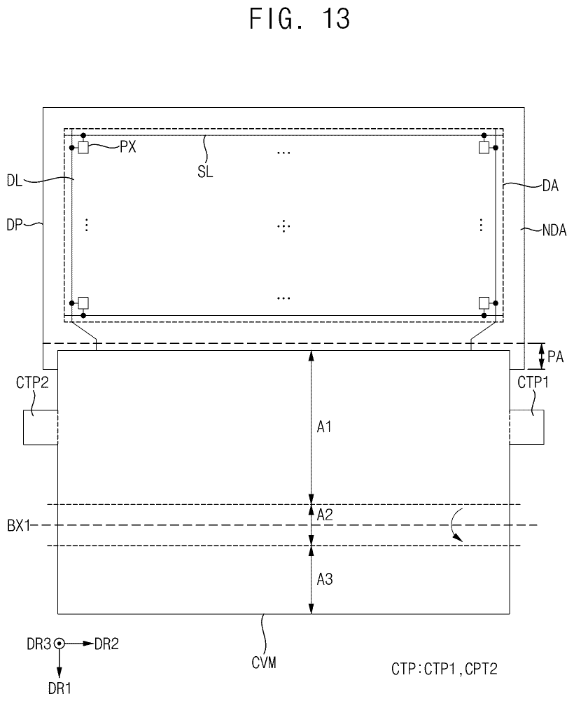

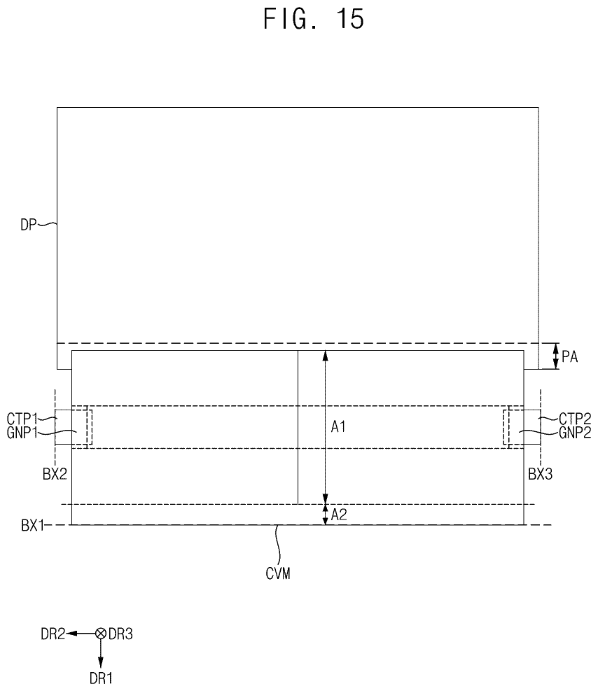

FIGS. 10-15 each is a view illustrating a method of manufacturing the display device of FIG. 1.

Referring to FIGS. 10-15, the first insulating layer CVM1 may include the first area A1, the second area A2, and the third area A3. The first area A1 may be an area corresponding to the upper surface of the first circuit board CB1, the second area A2 may be an area bent from the upper surface of the first circuit board CB1 toward the lower surface of the first circuit board CB1, and the third area A3 may be an area corresponding to the rear surface of the first circuit board CB1.

The conductive layer CVM2 may be on the first insulating layer CVM1. The conductive layer CVM2 may overlap the first insulating layer CVM1 in a plan view. The conductive layer CVM2 may include the first contact portion CTP1 and the second contact portion CTP2 in both sides (e.g., two opposing sides) of the conductive layer CVM2. For example, the first contact portion CTP1 may protrude from one side of the conductive layer CVM2 toward the second direction DR2. The second contact portion CTP2 may protrude from another side of the conductive layer CVM2 opposite to the one side in an opposite direction of the second direction DR2. For example, the first contact portion CTP1 may protrude from a side of the conductive layer CVM2 facing the second direction DR2 toward the second direction DR2. The second contact portion CTP2 may protrude from a side of the conductive layer CVM2 facing the opposite direction of the second direction DR2 toward the opposite direction of the second direction DR2. The first contact portion CTP1 and the second contact portion CTP2 may be in the first area A1.

The second insulating layer CVM3 may be on the conductive layer CVM2. After the first insulating layer CVM1, the conductive layer CVM2, and the second insulating layer CVM3 are sequentially provided, the cover member CVM including the first insulating layer CVM1, the conductive layer CVM2, and the second insulating layer CVM3 may be manufactured. After the cover member CVM is manufactured, the cover member CVM may be attached to the display panel DP.

Before the cover member CVM is attached to the display panel DP, the display panel DP and the first circuit board CB1 may be electrically connected. In one or more embodiments, the first ground portion GNP1 and the second ground portion GNP2 may be in each of both sides (e.g., two opposing sides) of the rear surface of the first circuit board CB1. The first ground portion GNP1 and the second ground portion GNP2 may be provided by removing a portion of the lower cover layer (e.g., the lower cover layer BSL1 of FIG. 8) to expose a portion of a conductive pattern BSL2.

The cover member CVM may contact a portion of the display panel DP in the pad area PA. For example, the cover member CVM may be combined to a portion of the display panel DP in the pad area PA through an adhesive material. As the cover member CVM contacts the portion of the display panel DP in the pad area PA, the cover member CVM may cover upper surfaces of each of the driving chip DIC and the first circuit board CB1.

A portion of the cover member CVM in the second area A2 may be bent along a first bending axis BX1 parallel (e.g., substantially parallel) to the second direction DR2. As the cover member CVM is bent along the first bending axis BX1, the cover member CVM may contact the lower plate layer (e.g., the lower plate layer SPL of FIG. 8). For example, the cover member CVM may be combined to the lower plate layer through an adhesive material. As the cover member CVM is combined to the lower plate layer, the third area A3 may face a rear surface of the first circuit board CB1.

After the cover member CVM is combined to the lower plate layer, the first contact portion CTP1 may be bent toward the first ground portion GNP1 along the second bending axis BX2 parallel (e.g., substantially parallel) to the first direction DR1. After the first contact portion CTP1 is bent, the first contact portion CTP1 and the first ground portion GNP1 may be combined through the first adhesive layer (e.g., the first adhesive layer ADL1 of FIG. 9). In one or more embodiments, the first contact portion CTP1 and the first ground portion GNP1 may be electrically connected to each other.

In one or more embodiments, after the cover member CVM is combined to the lower plate layer, the second contact portion CTP2 may be bent toward the second ground portion GNP2 along the third bending axis BX3 parallel (e.g., substantially parallel) to the second bending axis BX2. After the second contact portion CTP2 is bent, the second contact portion CTP2 and the second ground portion GNP2 may be combined through the second adhesive layer (e.g., the second adhesive layer ADL2 of FIG. 9). In one or more embodiments, the second contact portion CTP2 and the second ground portion GNP2 may be electrically connected to each other.

As the first contact portion CTP1 is connected to the first ground portion GNP1 and the second contact portion CTP2 is connected to the second ground portion GNP2, the display device DD of FIG. 1 may be manufactured.

As described in one or more embodiments, in the manufacturing method of the display device DD according to one or more embodiments of the present disclosure, after the first ground portion GNP1 and the second ground portion GNP2 are provided on both sides (e.g., two opposing sides) of the rear surface of the first circuit board CB1, the first contact portion CTP1 may be connected to the first ground portion GNP1 and the second contact portion CTP2 may be connected to the second ground portion GNP2. For example, the first contact portion CTP1 may be bent toward the first ground portion GNP1 to be connected to the first ground portion GNP1, and the second contact portion CTP2 may be bent toward the second ground portion GNP2 to be connected to the second ground portion GNP2. In one or more embodiments, because an additional process, such as adding a conductive (e.g., electrically conductive) material and/or attaching a structure for contact, to improve or enhance a contact between the cover member CVM and the first circuit board CB1 is not required, process time and cost to manufacture the display device DD may be shortened or reduced, and the process may be simplified.

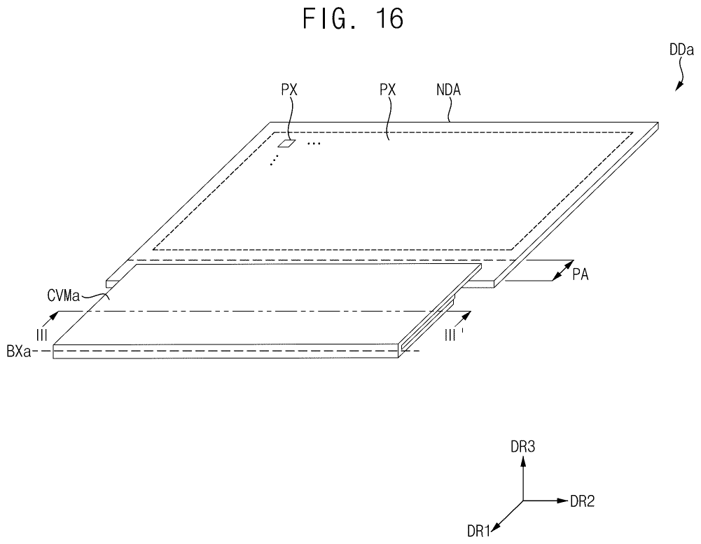

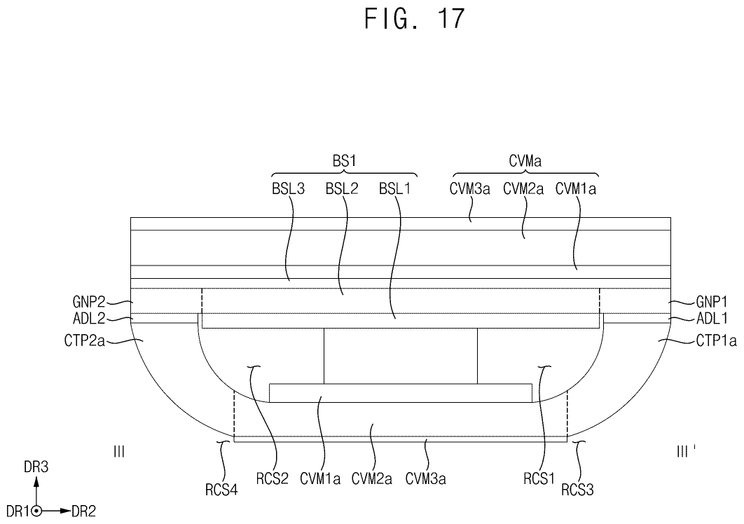

FIG. 16 is a perspective view illustrating a display device according to one or more embodiments of the present disclosure. FIG. 17 is a cross-sectional view illustrating a cross-section taken along a line III-III′ of FIG. 16.

A display device DDa as described with reference to FIGS. 16-17 may be substantially the same as or similar to the display device DD as described with reference to FIGS. 1-9, except for a cover member CVMa. Hereinafter, a certain content overlapping with that as described with reference to FIGS. 1-9 may not be provided or may be simplified.

Referring to FIGS. 16-17, a cover member CVMa may include a first insulating layer CVM1a, a conductive layer CVM2a, and a second insulating layer CVM3a. The conductive layer CVM2a may include a first contact portion CTP1a connected to the first ground portion GNP1 and a second contact portion CTP2a connected to the second ground portion GNP2. The first contact portion CTP1a and the second contact portion CTP2a may be in a third area A3. The cover member CVM may be bent along a bending axis BXa extending in the second direction DR2 in the second area A2.

A first recess RCS1 and a second recess RCS2 may be defined on both sides (e.g., two opposing sides) of the first insulating layer CVM1a in the third area A3. For example, the first recess RCS1 may be defined as being sunken in the opposite direction of the second direction DR2 from a side of the first insulating layer CVM1a facing the second direction DR2. The second recess RCS2 may be defined as being sunken in the second direction DR2 from a side of the first insulating layer CVM1a facing the opposite direction of the second direction DR2. The first recess RCS1 may expose the first contact portion CTP1a, and the second recess RCS2 may expose the second contact portion CTP2a. In one or more embodiments, a third recess RCS3 and a fourth recess RCS4 may be defined on both sides (e.g., two opposing sides) of the second insulating layer CVM2a in the third area A3.

The first contact portion CTP1a may be connected to the first ground portion GNP1 through the first recess RCS1. For example, the first contact portion CTP1a may be coupled to the first ground portion GNP1 through the first adhesive layer ADL1. In one or more embodiments, the second contact portion CTP2a may be connected to the second ground portion GNP2 through the second recess RCS2. For example, the second contact portion CTP2a may be coupled to the second ground portion GNP2 through the second adhesive layer ADL2. In one or more embodiments, the first adhesive layer ADL1 may be referred to as a first conductive (e.g., electrically conductive) tape, and the second adhesive layer ADL2 may be referred to as a second conductive (e.g., electrically conductive) tape.

In the cover member CVMa of FIG. 16, unlike the cover member CVM of FIG. 1, the first contact portion CTP1a and the second contact portion CTP2a may be in the third area A3 instead of the first area A1.

As described in one or more embodiments, in the display device DDa, the cover member CVMa may include the first contact member CTP1a connected to the first ground member GNP1 through the first recess RCS1 and the second contact member CTP2a connected to the second ground member GNP2 through the second recess RCS2. In one or more embodiments, a contact between the cover member CVMa and the first circuit board may be improved or enhanced, and a contact failure between the cover member CVMa and the first circuit board may be prevented (or a degree or occurrence of such contact failure may be reduced). In one or more embodiments, a durability of the display device DDa may be improved or enhanced.

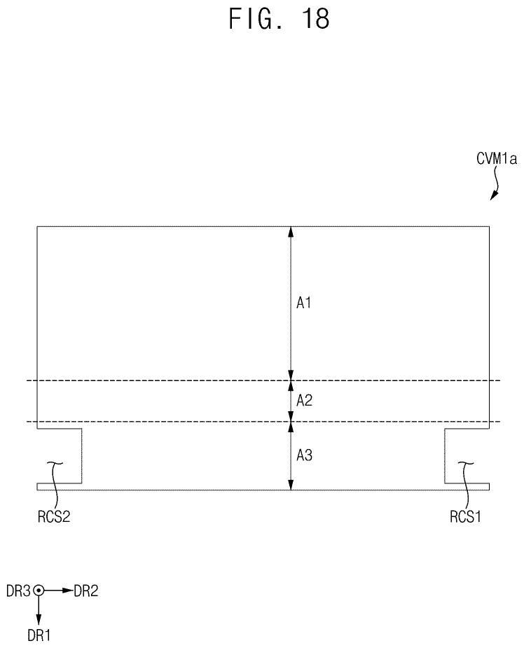

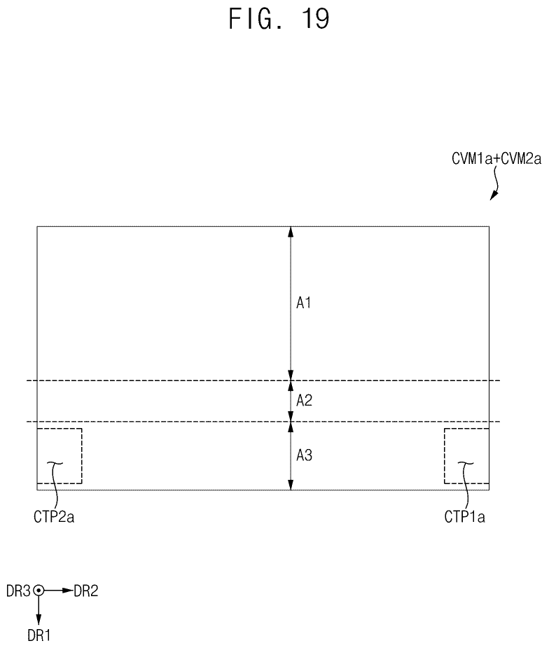

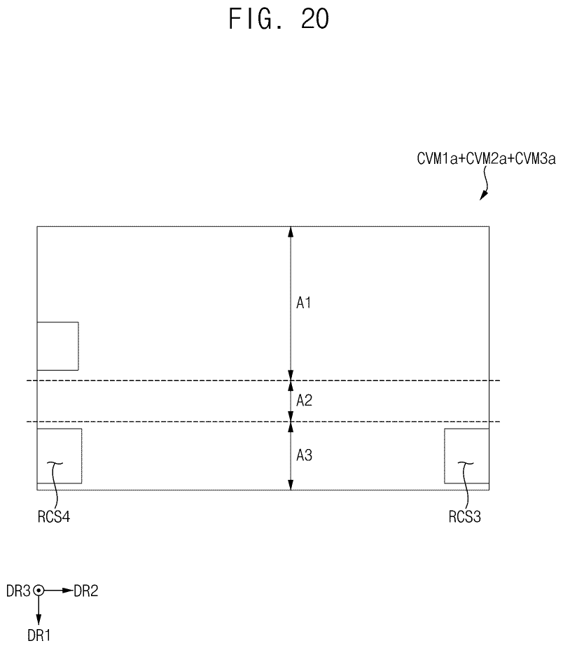

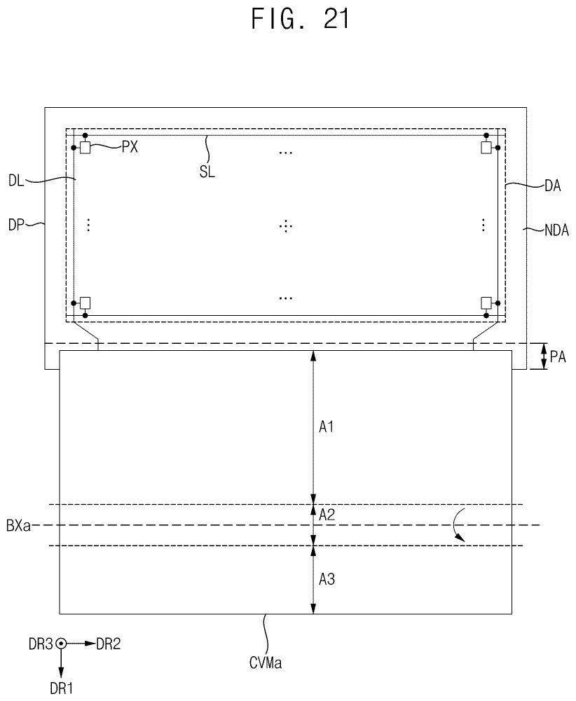

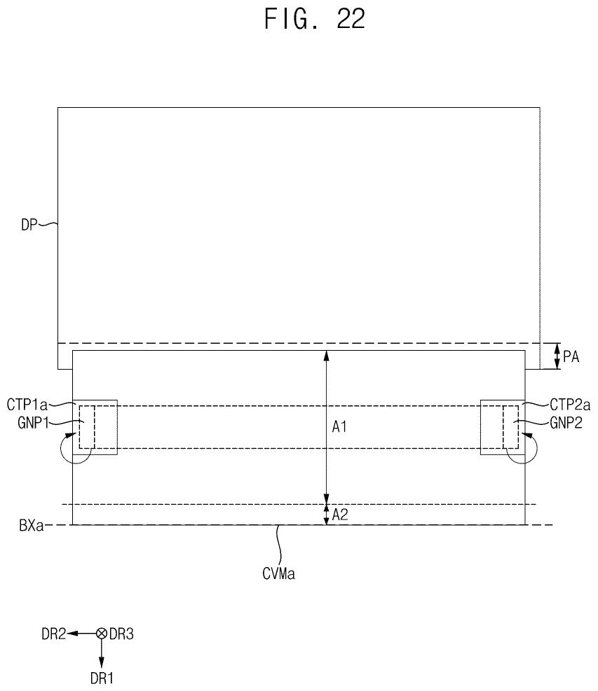

FIGS. 18-22 each is a view illustrating a method of manufacturing the display device of FIG. 16.

For example, FIGS. 18-22 each is a view illustrating a method of manufacturing the display device DDa as described with reference to FIGS. 16-17. Hereinafter, a certain content overlapping with the content as described with reference to FIGS. 16-17 may not be provided or may be simplified.

In one or more embodiments, the method of manufacturing a display device DDa as described with reference to FIGS. 18-22 may be substantially the same as or similar to the method of manufacturing the display device DD as described with reference to FIGS. 10-15, except for the method of connecting the first contact portion CTP1a and the second contact portion CTP2a to the first ground portion GNP1 and the second ground portion GNP2, respectively. Hereinafter, a certain content overlapping with the content as described with reference to FIGS. 10-15 may not be provided or may be simplified.

Referring to FIGS. 18-22, the first recess RCS1 and the second recess RCS2 may be defined on both sides (e.g., two opposing sides) of the first insulating layer CVM1a. The first recess RCS1 and the second recess RCS2 may be in a third area A3. The conductive layer CVM2a may be on the first insulating layer CVM1a. The conductive layer CVM2a may overlap the first recess RCS1 and/or the second recess RCS2. For example, one surface of the conductive layer CVM2a may be exposed by the first recess RCS1 and/or the second recess RCS2. The first contact portion CTP1a may be defined as a first portion of the conductive layer CVM2a exposed by the first recess RCS1. In one or more embodiments, the second contact portion CTP2a may be defined as a second portion of the conductive layer CVM2a exposed by the second recess RCS2.

The second insulating layer CVM3a may be on the conductive layer CVM2a. The third recess RCS3 and the fourth recess RCS4 may be defined on both sides (e.g., two opposing sides) of the second insulating layer CVM3a. The third recess RCS3 and the fourth recess RCS4 may be in the third area A3. Another side of the conductive layer CVM2a opposite to the one side may be exposed by the third recess RCS3 and the fourth recess RCS4. In one or more embodiments, the first recess RCS1 and the third recess RCS3 may overlap in a plan view. In one or more embodiments, the second recess RCS2 and the fourth recess RCS4 may overlap in a plan view. However, an overlapping relationship of the first recess RCS1, the second recess RCS2, the third recess RCS3, and/or the fourth recess RCS4 according to one or more embodiments of the present disclosure may not be limited thereto.

After the first insulating layer CVM1a, the conductive layer CVM2a, and the second insulating layer CVM3a are sequentially provided, the cover member CVMa including the first insulating layer CVM1a, the conductive layer CVM2a, and the second insulating layer CVM3a may be manufactured. After the cover member CVMa is manufactured, the cover member CVMa may be attached to the display panel DP. After the cover member CVMa is attached to the display panel DP, a portion of the cover member CVMa in the second area A2 along the bending axis BXa may be bent.

As the cover member CVMa is bent, one side of the first contact portion CTP1a may face one side of the first ground portion GNP1. As each of the first contact portion CTP1a and the first ground portion GNP1 is attached to the first adhesive layer (e.g., the first adhesive layer ADL1 of FIG. 17), the first contact portion CTP1a and the first ground portion GNP1 may be connected to each other.

As the cover member CVMa is bent, one side of the second contact portion CTP2a may face one side of the second ground portion GNP2. By attaching each of the surfaces of the second contact portion CTP2a and the second ground portion GNP2, as described in one or more embodiments, to the second adhesive layer (e.g., the second adhesive layer ADL2 of FIG. 17), the second contact portion CTP2a and the second ground portion GNP2 may be connected to each other.

As the first contact portion CTP1a is connected to the first ground portion GNP1a and the second contact portion CTP2a is connected to the second ground portion GNP2a, the display device DDa of FIG. 16 may be manufactured.

As described in one or more embodiments, in the manufacturing method of the display device DDa according to one or more embodiments of the present disclosure, after providing the first ground portion GNP1 and the second ground portion GNP2 on both sides (e.g., two opposing sides) of rear surface of the first circuit board (e.g., the first base substrate BS1 of FIG. 17), the first contact portion CTP1a may be connected to the first ground portion GNP1, and the second contact portion CTP2a may be connected to the second ground portion GNP2. For example, the first contact portion CTP1a may be connected to the first ground portion GNP1 through the first recess RCS1, and the second contact portion CTP2a may be connected to the second ground portion GNP2 through the second recess RCS2. In one or more embodiments, because no additional process, such as adding a conductive (e.g., electrically conductive) material and/or attaching a structure for contact, is required to improve or enhance contact between the cover member CVMa and the first circuit board, process time and cost for manufacturing the display device DDa may be shortened or reduced, and the process may be simplified.

The device and the method according to one or more embodiments may be applied to a display device included in a computer, a notebook, a mobile phone, a smartphone, a smart pad, a PMP, a PDA, an MP3 player, and/or the like.

One or more embodiments of the present disclosure provide an electronic device including the display device as described in one or more embodiments.

In one or more embodiments, the electronic device may be a smartphone, a television, a monitor, a tablet, an electric vehicle, a mobile phone, a tablet personal computer (PC), a mobile communication terminal, an electronic notebook, an electronic book, a portable multimedia player (PMP), a navigation device, an ultra-mobile PC (UMPC), a laptop computer, a billboard, an Internet of Things (IOT) device, a smartwatch, a watch phone, and/or a head-mounted display (HMD).

Although the devices, the methods, and the systems according to one or more embodiments have been described with reference to the drawings, the illustrated embodiments are examples and may be modified and changed by a person having ordinary skill in the art without departing from the spirit and scope of the present disclosure, including the appended claims and equivalents thereof.

What is claimed is:

1. A display device, comprising:
a substrate comprising a display area in which a plurality of pixels are provided and a pad area at one side of the display area;
a circuit board electrically connected to each of the plurality of pixels, spaced apart from the substrate in a first direction, and comprising a first ground portion and a second ground portion each in both sides; and
a cover member extending from an upper portion of the circuit board to a lower portion of the circuit board and comprising a first contact portion which is bent toward the first ground portion and connected to the first ground portion and a second contact portion which is bent toward the second ground portion and connected to the second ground portion.

2. The display device as claimed in claim 1, wherein the circuit board comprises:
a lower cover layer of which openings are defined in both sides;
an upper cover layer on the lower cover layer; and
a conductive pattern between the lower cover layer and the upper cover layer, in a cross-sectional view.

3. The display device as claimed in claim 2, wherein each of the first ground portion and the second ground portion is defined by a rear surface of the conductive pattern exposed by the openings.

4. The display device as claimed in claim 1, wherein the cover member comprises a first area adjacent to the substrate, a second area bent along a first bending axis extending in a second direction which intersects with the first direction, and a third area spaced apart from the first area, wherein the second area is between the first area and the third area.

5. The display device as claimed in claim 4, wherein the cover member comprises:
an insulating layer to cover an upper surface of the circuit board; and
a conductive layer on the insulating layer.

6. The display device as claimed in claim 5, wherein each of the first contact portion and the second contact portion is in the first area.

7. The display device as claimed in claim 5, wherein the first contact portion is defined as a first portion of the conductive layer bent toward the first ground portion along a second bending axis extending in the first direction.

8. The display device as claimed in claim 7, wherein the second ground portion is defined as a second portion of the conductive layer bent toward the second ground portion along a third bending axis parallel to the second bending axis.

9. The display device as claimed in claim 4, wherein the first contact portion protrudes from one side of the cover member in the second direction, in a plan view.

10. The display device as claimed in claim 9, wherein the second contact portion protrudes from another side of the cover member opposite to the one side of the cover member in a direction opposite to the second direction.

11. The display device as claimed in claim 1, wherein the first contact portion and the second contact portion are electrically connected to the first ground portion and the second ground portion through a conductive tape, respectively.

12. A display device, comprising:
a substrate comprising a display area in which a plurality of pixels are provided and a pad area at one side of the display area;
a circuit board electrically connected to each of the plurality of pixels, spaced apart from the substrate in a first direction, and comprising a first ground portion and a second ground portion each in both sides; and
a cover member extending from an upper portion of the circuit board to a lower portion of the circuit board and comprising:
an insulating layer to cover an upper surface of the circuit board and of which a first recess and a second recess are defined in both sides; and
a conductive layer on the insulating layer, wherein the conductive layer is connected to the first ground portion through the first recess and is connected to the second ground portion through the second recess.

13. The display device as claimed in claim 12, wherein the cover member comprises a first area adjacent to the substrate, a second area bent along a first bending axis extending in a second direction which intersects with the first direction, and a third area spaced apart from the first area, wherein the second area is between the first area and the third area.

14. The display device as claimed in claim 13, wherein each of the first recess and the second recess is in the third area.

15. The display device as claimed in claim 13, wherein the first recess is recessed from one side of the insulating layer in a direction opposite to the second direction and exposes the first ground portion, and
the second recess is recessed from an another side opposite to the one side of the insulating layer in the second direction and exposes the second ground portion.

16. The display device as claimed in claim 12, wherein a first portion of the conductive layer, which is connected to the first ground portion through the first recess, is electrically connected to the first ground portion through a first conductive tape, and
a second portion of the conductive layer, which is connected to the second ground portion through the second recess, is electrically connected to the second ground portion through a second conductive tape.

17. An electronic device, comprising a display device comprising:
a substrate comprising a display area in which a plurality of pixels are provided and a pad area at one side of the display area;
a circuit board electrically connected to each of the plurality of pixels, spaced apart from the substrate in a first direction, and comprising a first ground portion and a second ground portion each in both sides; and
a cover member extending from an upper portion of the circuit board to a lower portion of the circuit board and comprising a first contact portion which is bent toward the first ground portion and connected to the first ground portion and a second contact portion which is bent toward the second ground portion and connected to the second ground portion.

18. The electronic device as claimed in claim 17, wherein the electronic device is a smartphone, a television, a monitor, a tablet, an electric vehicle, a mobile phone, a tablet personal computer (PC), a mobile communication terminal, an electronic notebook, an electronic book, a portable multimedia player (PMP), a navigation device, an ultra-mobile PC (UMPC), a laptop computer, a billboard, an Internet of Things (IOT) device, a smartwatch, a watch phone, or a head-mounted display (HMD).
